(19) United States
(12) Patent Application Publication
(10) Pub. No.: US 2013/0155589 A1
(43) Pub. Date: Jun. 20, 2013

(54) ELECTRONIC DEVICE

(71) Applicant: Arisa Takabayashi, Tokyo (JP)

(72) Inventor: Arisa Takabayashi, Tokyo (JP)

(73) Assignee: PANASONIC CORPORATION, Osaka (JP)

(21) Appl. No.: 13/814,704

(22) PCT Filed: Mar. 16, 2012
(86) PCT No.: PCT/JP2012/001875

§ 371 Date: Feb. 6, 2013

(30) Foreign Application Priority Data
Mar. 30, 2011 (JP) 2011-075834

(51) Int. Cl. H05K 5/02

(52) U.S. Cl. CPC H05K 5/0286
USPC 361/679.01

(57) ABSTRACT

Protruding parts 33 are provided on a bottom surface 242 of a battery accommodating part 24 in a front part of a card accommodating part 30 provided in an inner wall part 241 of the battery accommodating part 24. A dimension H1 of protrusion of the protruding part 33 is set to be equal to or smaller than a height H2 from the bottom surface 242 to a lower end edge of an insert and detaching opening 31 of the card accommodating part 30. When a card 13 is accommodated in the card accommodating part 30, the card 13 can be inserted into the insert and detaching opening 31 of the card accommodating part 30 along the protruding parts 33 without lifting an end of the card 13. Thus, the card 13 can be easily accommodated in the card accommodating part 30.

### TECHNICAL FIELD

The present invention relates to an electronic device having an insert and detaching opening of a card accommodating part in an inner wall part of a battery accommodating part.

### BACKGROUND ART

Usually, in a portable terminal as an electronic device, an SIM card or a memory card is accommodated in a casing (for instance, see patent literature 1).

As shown in FIGS. 8A and 8B, in a portable terminal device 100 disclosed in the patent literature 1, a battery accommodating part 102 is provided in a casing 101. The battery accommodating part 102 accommodates and fixes a battery (an illustration is omitted) for supplying an electric power to the portable terminal device 100 and the battery is covered with a battery cover (an illustration is omitted).

In the battery accommodating part 102, an SIM card accommodating part 103 is provided. The SIM card accommodating part 103 has an SIM connector 105 fixed and electrically connected to a board 104 to accommodate an SIM (Subscriber Identity Module) card (an illustration is omitted). In the SIM card accommodating part 103, a terminal part of the SIM connector 105 is electrically connected to a terminal part of the SIM card.

In the SIM card accommodating part 103, an SIM lock 106 is provided. The SIM lock 106 is formed with a plate 107 attached to the SIM card accommodating part 103 and has a plurality of plate springs 108 in a central part of the plate 107.

Thus, when the SIM card is accommodated in the SIM card accommodating part 103, the SIM card is held and fixed between a terminal part 105A of the SIM connector 105 and the plate springs 108 of the plate 107.

### CITATION LIST

### Patent Literature

Patent Literature 1: Japanese Patent No. 4539490 (FIG. 1)

### SUMMARY OF THE INVENTION

### Technical Problem

However, in recent years, in order to reduce the thickness of a portable terminal, a card accommodating part is provided in an inner wall part of a battery accommodating part.

In this case, since an opening for inserting a card into the card accommodating part is provided at a position higher than a bottom surface of the battery accommodating part due to a positional relation to a circuit board, the card needs to be inserted into the opening under a state that the card is slightly lifted. Thus, a problem arises that the card is hardly inserted into the opening.

Especially, since the card is small, the card is hardly held and inserted by fingers.

The present invention is devised to solve the usual problem and it is an object of the present invention to provide an electronic device in which a card can be easily accommodated in a card accommodating part provided in a battery accommodating part.

### Solution to Problem

An electronic device according to the invention includes a casing; a battery accommodating part provided in the casing; a card accommodating part provided in an inner wall part of the battery accommodating part; and protruding parts provided on a bottom surface of the battery accommodating part, wherein a dimension of protrusion from the bottom surface to a top part of the protruding part is set to be equal to or smaller than a dimension of accommodating height from the bottom surface to a lower end edge of an insert and detaching opening of the card accommodating part.

In the electronic device according to the invention, the protruding parts are provided on the bottom surface of the battery accommodating part and a plurality of protruding parts are provided correspondingly to both end parts in the direction of width of the opening of the card accommodating part.

In the electronic device according to the invention, the protruding parts have hemispherical forms.

In the electronic device according to the invention, a sheet member is stuck on the bottom surface of the battery accommodating part and the protruding parts are provided at positions which do not interfere with the sheet member.

### Advantageous Effects of Invention

In the present invention, protruding parts are provided on a bottom surface of a battery accommodating part in a front part of a card accommodating part provided in an inner wall part of the battery accommodating part. A dimension of protrusion of the protruding part is set to be equal to or smaller than a height from the bottom surface to a lower end edge of an insert and detaching opening of the card accommodating part. Accordingly, when a card is accommodated in the card accommodating part, the card can be inserted into the insert and detaching opening of the card accommodating part along the protruding parts without lifting an end of the card. Thus, the electronic device can be provided in which the card can be effectively easily inserted into the card accommodating part.

### BRIEF DESCRIPTION OF DRAWINGS

FIG. 1 is a perspective view of a portable terminal as an electronic device of an exemplary embodiment according to the present invention.

FIG. 2 is a perspective view of a battery accommodating part and a card accommodating part.

FIG. 3 is a sectional view taken along a position in FIG. 2.

FIG. 4 is a schematic sectional view showing a relation between a dimension of height of a protruding part, a dimension of height of an insert and detaching opening and a thickness of a sheet member.

FIG. 5 is a plan view showing a positional relation between a key device and the protruding part.

FIG. 6 is a sectional view showing a modified example of the protruding part.

FIG. 7 is a plan view showing an accommodating state of an SIM card.

FIGS. 8A and 8B show a usual portable terminal device. FIG. 8A is a perspective view showing a state that an SIM lock is detached. FIG. 8B is a perspective view showing a state that the SIM lock is attached.

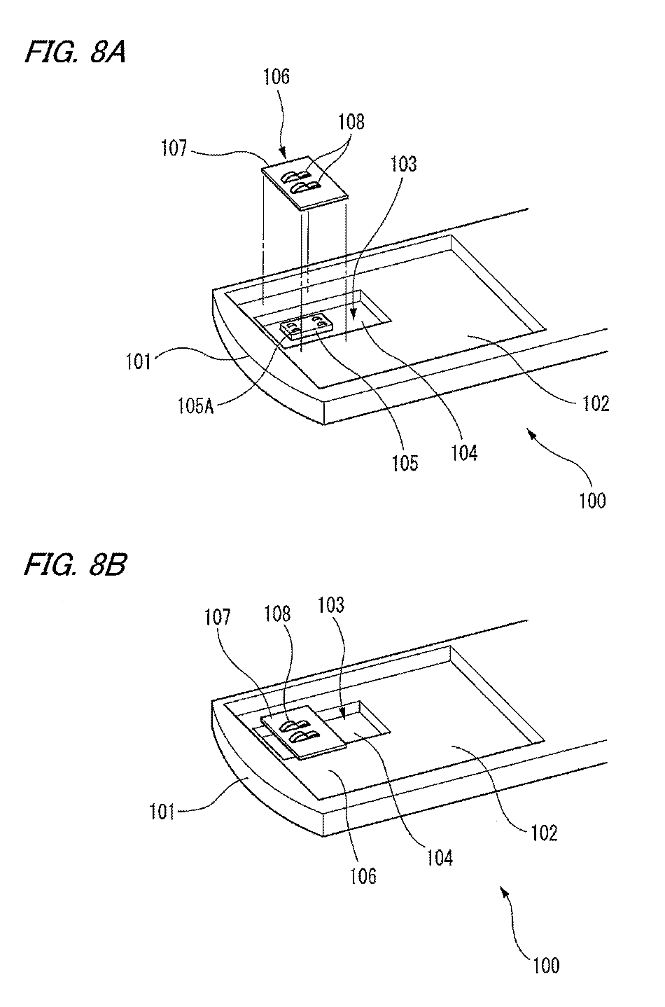

### DESCRIPTION OF EMBODIMENTS

Now, an electronic device of an exemplary embodiment according to the present invention will be described below by using the drawings.

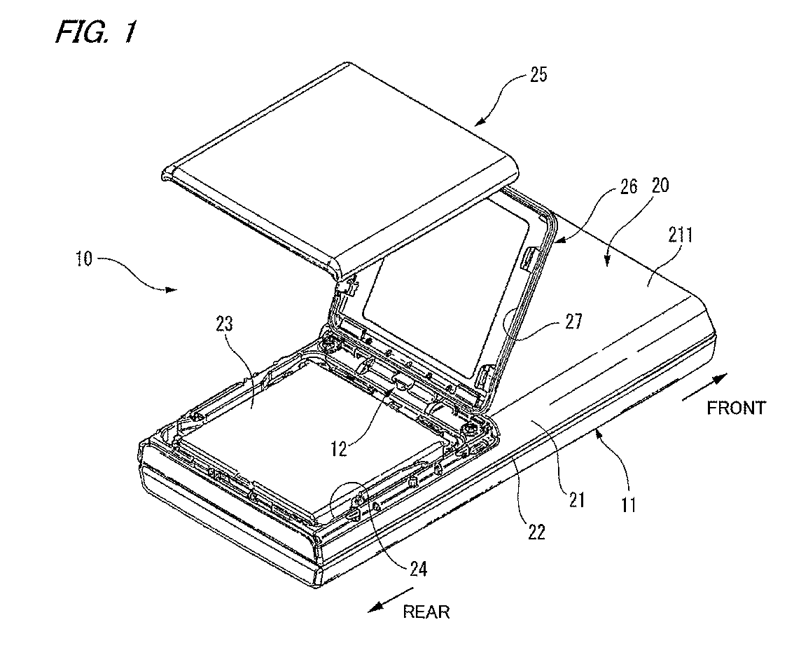

As shown in FIG. 1, a portable terminal 10 as the electronic device of the exemplary embodiment according to the present invention includes a first casing (a casing) 20 formed substantially in the shape of a rectangular box, a second casing 11 formed substantially in the shape of a rectangular box and a connecting part (an illustration is omitted) which connects the first casing 20 to the second casing 11 so as to freely slide or rotate.

Accordingly, the portable terminal 10 is relatively opened and closed on the connecting part as a center so that the portable terminal 10 may take a portable state (see FIG. 1) that the first casing 20 and the second casing 11 are overlapped on each other and an expanded state that the first casing and the second casing are opened through the connecting part.

The first casing 20 has a thin rectangular box shaped case 21 having a lower surface (a lower surface in FIG. 1) opened and a cover 22 which covers the opening of the case 21. On a surface (a lower surface in FIG. 1), an operating part provided with operating keys is provided. Further, the second casing 11 has the rectangular box shape and is provided with a display part formed with a liquid crystal display plate on a surface (a lower surface in FIG. 1).

In one side (a rear side) of a longitudinal direction in a bottom surface (an upper surface in FIG. 1) 211 of the case 21 of the first casing 20, a battery accommodating part 24 which accommodates a battery pack 23 is provided. In the battery accommodating part 24, a first cover member 25 is provided outside (an outer part side) of the case 21 and a second cover member 26 is provided inside (an inner part side of the case 21) the first cover member 25.

The first cover member 25 is slid in the longitudinal direction of the first casing 20 to be detachably attached thereto.

The second cover member 26 is a member for waterproofing the battery accommodating part 24 to protect the battery pack 23 from water and provided so as to freely rotate relative to the first casing 20 through a hinge part 12. The second cover member 26 is a rectangular plate member and a packing 27 is attached thereto along an outer peripheral edge. The packing 27 seals an opening of the battery accommodating part 24 over an entire periphery.

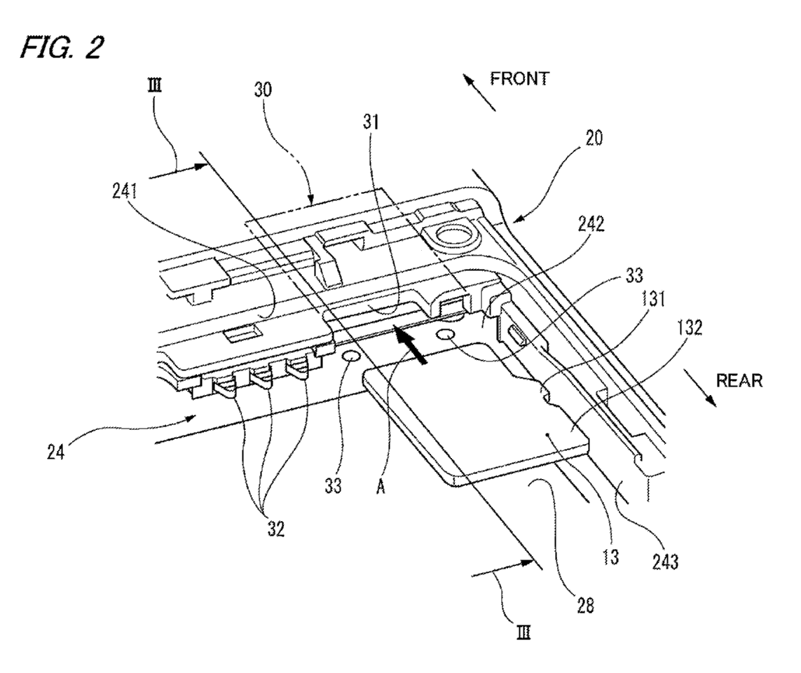

As shown in FIG. 2, in a part near to an end part in the direction of width in an inner wall part 241 of a front side of the battery accommodating part 24, a card accommodating part 30 is provided which accommodates a card 13 such as an SD card. An insert and detaching opening 31 for taking in and out the card 13 of the card accommodating part 30 is opened in a rear side of the card accommodating part 30. In a central side in the direction of width in the inner wall part 241 of the front side of the battery accommodating part 24, a plurality of connecting terminals 32 which electrically connect the battery pack 23 are provided to protrude to the battery accommodating part adjacently to the insert and detaching opening 31.

Further, on a bottom surface 242 of the battery accommodating part, a sheet member 28 on which information such as names of parts or production dates is described is stuck.

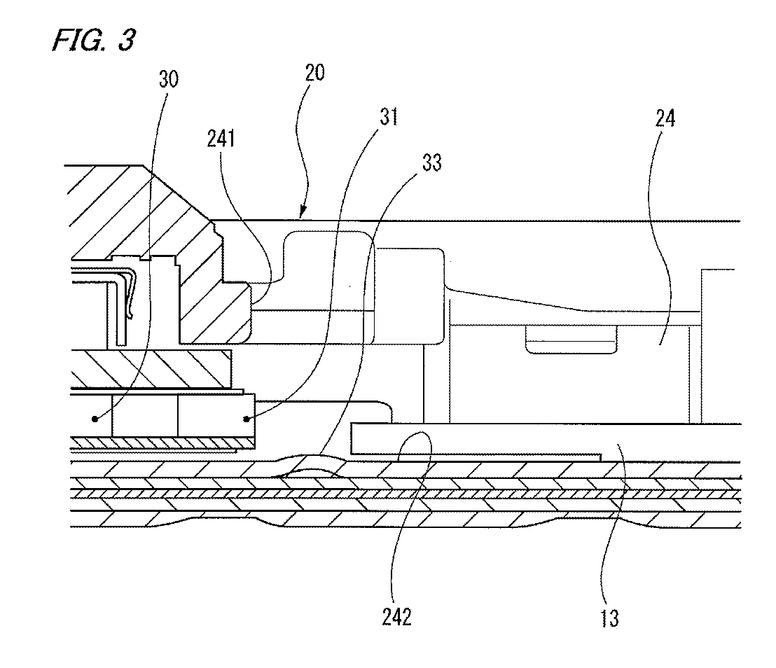

As shown in FIG. 2 and FIG. 3, in a rear side (the battery accommodating part 24 side) of the insert and detaching opening 31 of the card accommodating part 30 on the bottom surface 242 of the battery accommodating part 24, a pair of protruding parts 33 and 33 are provided.

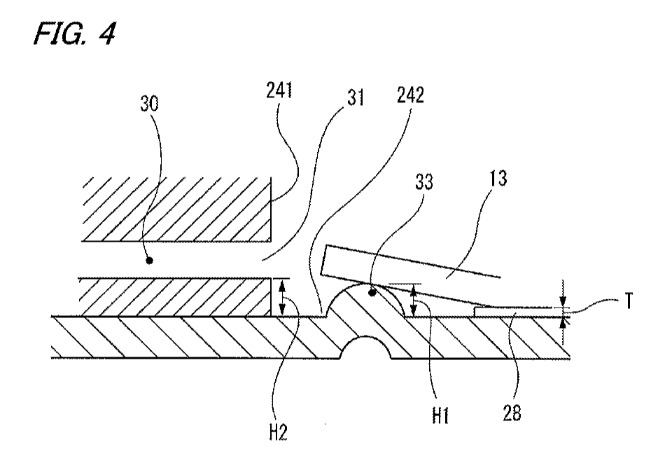

As shown in FIG. 4, in the protruding part 33, a dimension H1 of protrusion from the bottom surface 242 to a top part of the protruding part 33 is set to be equal to or smaller than a dimension H2 of accommodating height from the bottom surface 242 to a lower end edge of the insert and detaching opening 31 of the card accommodating part 30. Further, a height of the protruding part 33 is set to be equal to or larger than a dimension T of thickness of the sheet member 28.

Namely, the dimensions are set to have a relation expressed by H2>H1>T.

As shown in FIG. 2, the protruding parts 33 are provided correspondingly to both end parts in the direction of width of the insert and detaching opening 31 and may be formed in, for instance, hemispherical shapes. Otherwise, at least opposite sides (namely, rear half parts) to the insert and detaching opening part 31 may be formed in the hemispherical shapes.

The protruding parts 33 are provided at positions which do not interfere with the sheet member 28 stuck to the bottom surface 242 of the battery accommodating part 24.

Now, an inserting method for the card 13 will be described below.

As shown in FIG. 2, the card 13 is mounted on the bottom surface 242 of the battery accommodating part 24 and guide parts 131 and 132 provided in a side surface of the card 13 are allowed to come into contact with a side surface 243 of the battery accommodating part 24. Under this state, the card 13 is pressed by a finger to slide the card forward (a direction shown by an arrow mark A in FIG. 2).

At this time, an end part of the card 13 is lifted upward by the protruding parts 33 (see FIG. 4) and the end part is directed toward the insert and detaching opening 31 of the card accommodating part 30.

Further, the card 13 is slid forward to insert the card 13 into the card accommodating part 30 from the insert and detaching opening 31.

In the portable terminal 10 as the electronic device of the above-described exemplary embodiment of the present invention, the protruding parts 33 are provided on the bottom surface 242 of the battery accommodating part 24 in the front part of the card accommodating part 30 provided in the inner wall part 241 of the battery accommodating part 24. The dimension H1 of protrusion of the protruding part 33 is set to be equal to or smaller than the height H2 from the bottom surface 242 to the lower end edge of the insert and detaching opening 31 of the card accommodating part 30.

Accordingly, when the card 13 is accommodated in the card accommodating part 30, the card 13 can be inserted into the insert and detaching opening 31 of the card accommodating part 30 along the protruding parts 33 without lifting the end of the card 13. Thus, the card 13 can be easily accommodated in the card accommodating part 30.

Further, since the protruding parts 33 are provided at the positions which do not interfere with the sheet member 28 stuck to the bottom surface 242 of the battery accommodating part 24, a prescribed height is ensured and the card 13 can be prevented from hardly sliding.

Further, since the height of the protruding part 33 is set to be equal to or larger than the dimension T of thickness of the sheet member 28, when the card 13 is taken out from the insert and detaching opening 31, the card 13 can be prevented from being caught by an end part of the sheet member 28 and can be easily taken out.

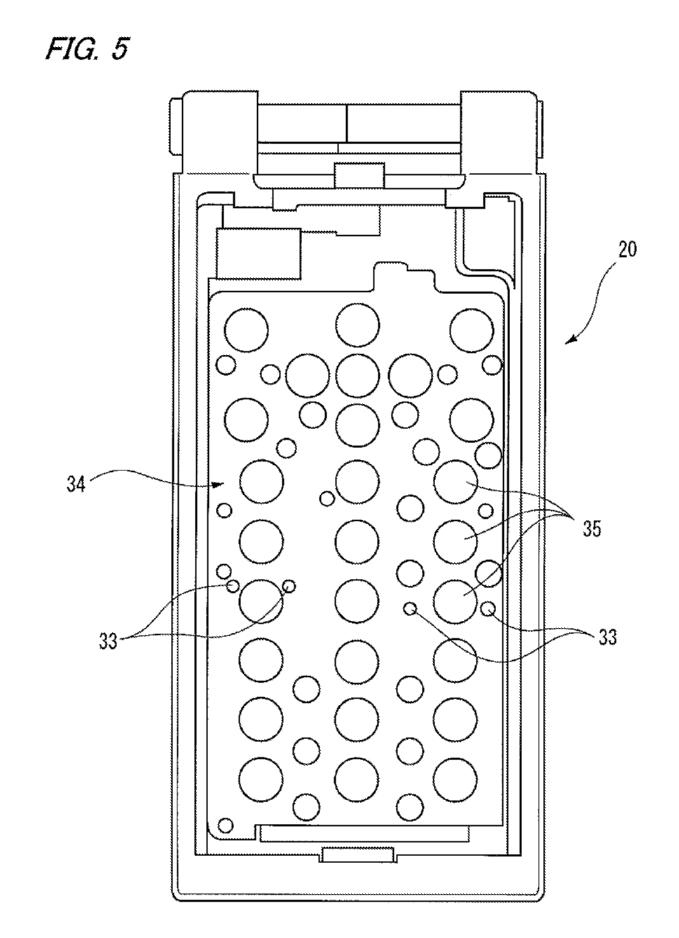

Further, the one pair of protruding parts 33 and 33 are separately provided correspondingly to both the end parts in the direction of width of the insert and detaching opening 31. Accordingly, as shown in FIG. 5, when a key device 34 is provided on an opposite side surface to the battery accommodating part 24 in the first casing 20, the protruding parts can be provided by selecting positions which do not interfere with key frames 35 of the key device 34.

The electronic device of the present invention is not limited to the above-described exemplary embodiment and may be suitably modified and improved.

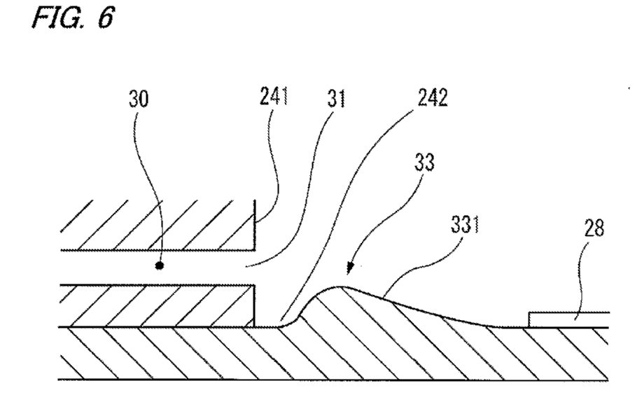

For instance, in the above-described exemplary embodiment, an example is shown that the protruding parts 33 are formed in the hemispherical shapes; however, as shown in FIG. 6, an inclined surface 331 directed toward the insert and detaching opening 31 may be provided.

Further, an example is shown that the one pair of protruding parts 33 are provided correspondingly to both the end parts in the direction of width of the insert and detaching opening 31, however, one protruding part may be provided which is long in the direction of width of the insert and detaching opening 31. In this case, a form may be provided which is obtained, for instance, by dividing a circular cylinder in a longitudinal direction.

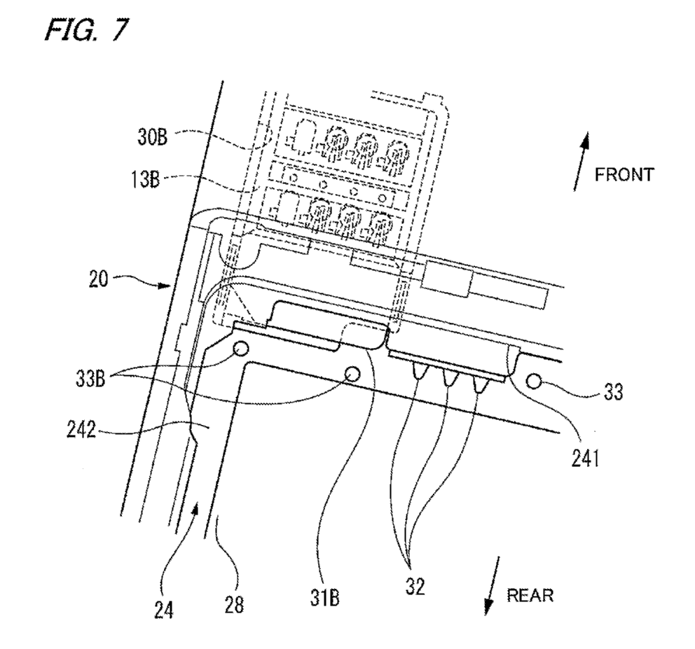

Further, in the above-described exemplary embodiment, the memory card such as the SD card is exemplified; however, as shown in FIG. 7, an SIM card 13B accommodated in a left side end part of the battery accommodating part 24 may be similarly applied. Namely, one pair of protruding parts 33B and 33B are provided in a rear side (the battery accommodating part 24 side) of an insert and detaching opening 31B of a card accommodating part 30B.

Thus, the SIM card 13B can be easily accommodated in the card accommodating part 30B. Further, when the card is taken out, the card can be prevented from being caught by the sheet member 28.

This invention is based on Japanese Patent Application (Japanese Patent Application No. 2011-075834) filed on Mar. 30, 2011, the content of which is incorporated herein by reference.

### INDUSTRIAL APPLICABILITY

As described above, in the electronic device according to the present invention, the protruding parts are provided on the bottom surface of the battery accommodating part in the front part of the card accommodating part provided in an inner wall part of the battery accommodating part. The dimension of protrusion of the protruding part is set to be equal to or smaller than the height from the bottom surface to the lower end edge of the insert and detaching opening of the card accommodating part. Accordingly, when the card is accommodated in the card accommodating part, the card can be inserted into the insert and detaching opening of the card accommodating part along the protruding parts without lifting the end of the card. Thus, the electronic device is useful as an electronic device having an effect that the card can be easily accommodated in the card accommodating part and having the insert and detaching opening of the card accommodating part in the inner wall part of the battery accommodating part.

### REFERENCE SIGNS LIST

10 . . . portable terminal (electronic device) 20 . . . first casing (casing) 24 . . . battery accommodating part 241 . . . inner wall part 242 . . . bottom surface 30, 30B . . . card accommodating part 31, 31B . . . insert and detaching opening 33, 33B . . . protruding part

1. An electronic device including:
a casing;
a battery accommodating part provided in the casing;
a card accommodating part provided in an inner wall part of the battery accommodating part; and
one or more protruding parts provided on a bottom surface of the battery accommodating part, wherein
a dimension of protrusion from the bottom surface to a top part of the protruding part is set to be equal to or smaller than a dimension of accommodating height from the bottom surface to a lower end edge of an insert and detaching opening of the card accommodating part.

2. An electronic device according to claim 1, wherein the protruding parts are provided on the bottom surface of the battery accommodating part and a plurality of protruding parts are provided correspondingly to both end parts in the direction of width of the opening of the card accommodating part.

3. An electronic device according to claim 1, wherein the one or more protruding parts have hemispherical forms.

4. An electronic device according to claim 1, wherein a sheet member is stuck on the bottom surface of the battery accommodating part and the one or more protruding parts are provided at positions which do not interfere with the sheet member.

5. An electronic device according to claim 2, wherein the plurality of protruding parts have hemispherical forms.

6. An electronic device according to claim 2, wherein a sheet member is stuck on the bottom surface of the battery accommodating part and the plurality of protruding parts are provided at positions which do not interfere with the sheet member.
